(19) United States
(12) Patent Application Publication
(10) Pub. No.: US 2013/0105299 A1
(43) Pub. Date: May 2, 2013

(54) VACUUM DEPOSITION METHOD FOR FORMING GRADIENT PATTERNS USING VACUUM DEVICE

(71) Applicant: Sang Yeong Kim, Changwon-si (KR)

(72) Inventor: Sang Yeong Kim, Changwon-si (KR)

(21) Appl. No.: 13/395,413

(22) PCT Filed: Apr. 5, 2011
(86) PCT No.: PCT/KR2011/002353

§ 371 Date: Jan. 14, 2013

(30) Foreign Application Priority Data
Jun. 1, 2010 (KR) 1020100051927

(51) Int. Cl. C23C 14/34

(52) U.S. Cl. CPC C23C 14/34
USPC 204/192.15; 204/192.12

(57) ABSTRACT

Disclosed therein is a vacuum deposition method for forming gradient patterns using a vacuum device. The vacuum device comprises vacuum chambers (8) containing a substrate (4) and metal targets (1) therein and a blocking member (7) interposed between the substrate (4) and the metal targets (1). When voltage is applied to the metal targets (1), atoms (5) popping out from the metal targets (1) are deposited onto the substrate (4) in such a way that the amount of atoms deposited on the substrate (4) is gradually decreased from the edge toward the center of the blocking member (7) due to interruption of the blocking member (7).

### BACKGROUND OF THE INVENTION

1. Field of the Invention

The present invention relates to a vacuum deposition method for carrying out vacuum deposition onto the surface of a product using a vacuum device, which additionally includes a plurality of blocking members to provide various patterns according to their arranged conditions, and more particularly, to a vacuum deposition method for forming gradient patterns using a vacuum device that forms a gradient-patterned film on a substrate located at the back of the blocking members by depositing atoms of metal targets on the substrate.

2. Background Art

In general, vacuum deposition is a method to apply negative voltage to metal targets by a vacuum device, which includes vacuum chambers, a substrate, and the metal targets. When the negative voltage is applied to the metal targets, argon is ionized by electrons emitted from the cathode and becomes argon plasma, and positive argon ions in the argon plasma are accelerated toward the metal targets by a potential difference. Thereby, the argon ions collide with the surfaces of the metal targets, so that neutral atoms of the metal targets pop out and are deposited on the substrate.

Such a conventional vacuum deposition method is environmental-friendly and has been recognized as a superior method to protect products, but because it is deposition of a solid color, it remains a problem to supplement its default in an aspect of design.

### SUMMARY OF THE INVENTION

Accordingly, the present invention has been made to solve the above-mentioned problems occurring in the prior arts, and it is an object of the present invention to provide a vacuum deposition method for forming gradient patterns using a vacuum device, which can break the monotony of the conventional solid-color deposition and provide an artistic and esthetic sense to thereby produce high-quality products with fresh and beautiful colors, and which is low in additional installation fee because blocking members for forming gradient patterns are additionally mounted to the conventional vacuum deposition device.

To accomplish the above object, according to the present invention, there is provided a vacuum deposition method for forming gradient patterns using a vacuum device, which includes vacuum chambers, a substrate and metal targets contained in the vacuum chambers, and a blocking member interposed between the substrate and the metal targets, the vacuum deposition method comprising the steps of: applying negative voltage to the metal targets; ionizing argon by electrons emitted from a cathode; activating the ionized argon to be in a plasma state; accelerating positive argon ions in the argon plasma toward the metal targets by a potential difference; colliding the ions with the surfaces of the metal targets to thereby pop out neutral atoms from the metal targets; and depositing the atoms onto the substrate in such a way that the amount of atoms deposited on the substrate is gradually decreased from the edge toward the center of the blocking member due to interruption of the blocking member.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a configuration view of a conventional vacuum deposition device;

FIG. 2 is a schematic diagram showing the principle of a conventional vacuum deposition;

FIG. 3 is a configuration view of a vacuum deposition method for forming gradient patterns using a vacuum device according to the present invention;

FIG. 4 is a schematic diagram showing the principle for forming the gradient patterns through vacuum deposition using the vacuum device according to the present invention;

FIG. 5 is a view showing an example that blocking members are arranged vertically;

FIG. 6 is a view showing a gradient pattern formed by the blocking members arranged vertically;

FIG. 7 is a view showing an example that blocking members are arranged horizontally;

FIG. 8 is a view showing a gradient pattern formed by the blocking members arranged horizontally;

FIG. 9 is a view showing another example of the blocking members according to the present invention; and

FIG. 10 is a view showing a gradient pattern formed by the blocking members of FIG. 9.

### DETAILED DESCRIPTION OF THE PREFERRED EMBODIMENT

Reference will be now made in detail to the preferred embodiment of the present invention with reference to the attached drawings.

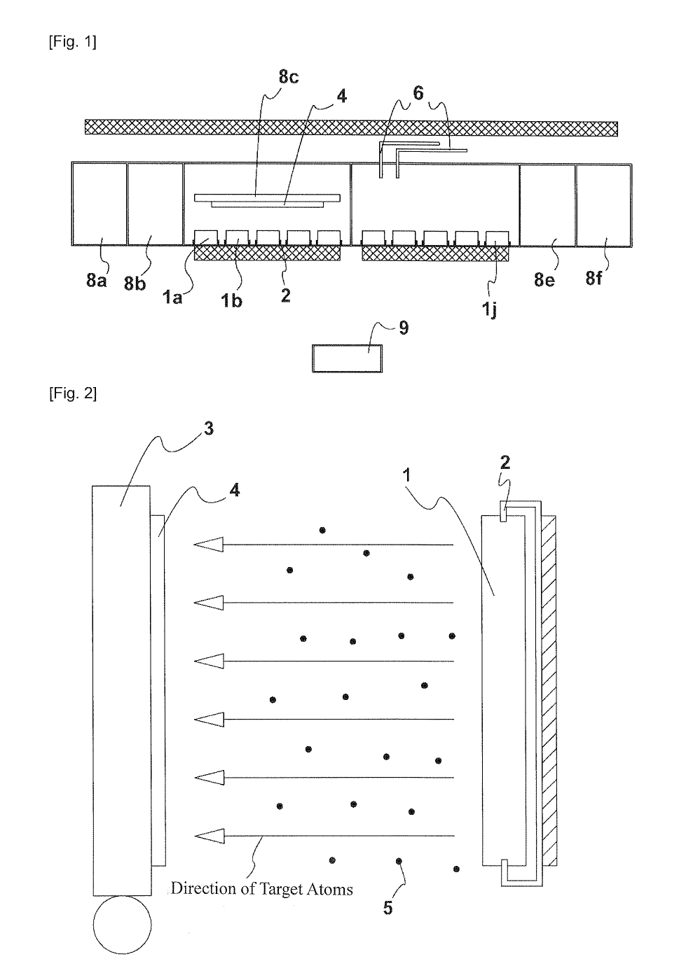

FIG. 1 is a configuration view of a conventional vacuum deposition device. In FIG. 1, the vacuum deposition device includes: a number of chambers 8a to 8f controllable in the degree of vacuum; one or more metal targets 1a to 1j disposed inside the chambers 8; a carrier 3 located in front of the metal targets 1 to move a substrate 4; a cathode 2 for applying negative electrode to the metal targets 1; and a gas tube 6 for supplying gas, such as argon, oxygen, nitrogen, or others.

As peripherals, the vacuum deposition device further includes a power supply 9, a control box allowing a user to control working conditions, and an AC-DC converter sued according to characteristics of products.

The first chamber 8a out of the plural chambers 8 is an entry chamber for introducing the substrate into the device, and the second chamber 8b is a buffer chamber, and the introduced substrate 4 enters the third chamber 8c after passing through the second chamber 8b.

The third chamber 8c and the fourth chamber 8d are chambers for depositing the substrate 4, and according to circumstances, only one of the third and fourth chambers 8c and 8d can be used.

The fifth chamber 8e is a buffer chamber like the second chamber 8b, in more detail, an exit buffer chamber, and the sixth chamber 8f is an exit lock chamber.

One or more metal targets 8 are contained in the third chamber 8e and the fourth chamber 8d.

FIG. 2 is a schematic diagram showing the principle of a conventional vacuum deposition. The metal targets 1 of a metal plate type are disposed inside the vacuum chambers 8, and negative voltage is applied to the metal targets 1, so that argon is ionized by electrons emitted from the cathode 2. After that, argon is activated and becomes in a plasma state, and positive argon ions in the argon plasma is accelerated toward the metal targets 1 by a potential difference, so that the ions collide with the surfaces of the metal targets 1, whereby neutral atoms 5 of the metal targets pop out and are deposited on the substrate 4.

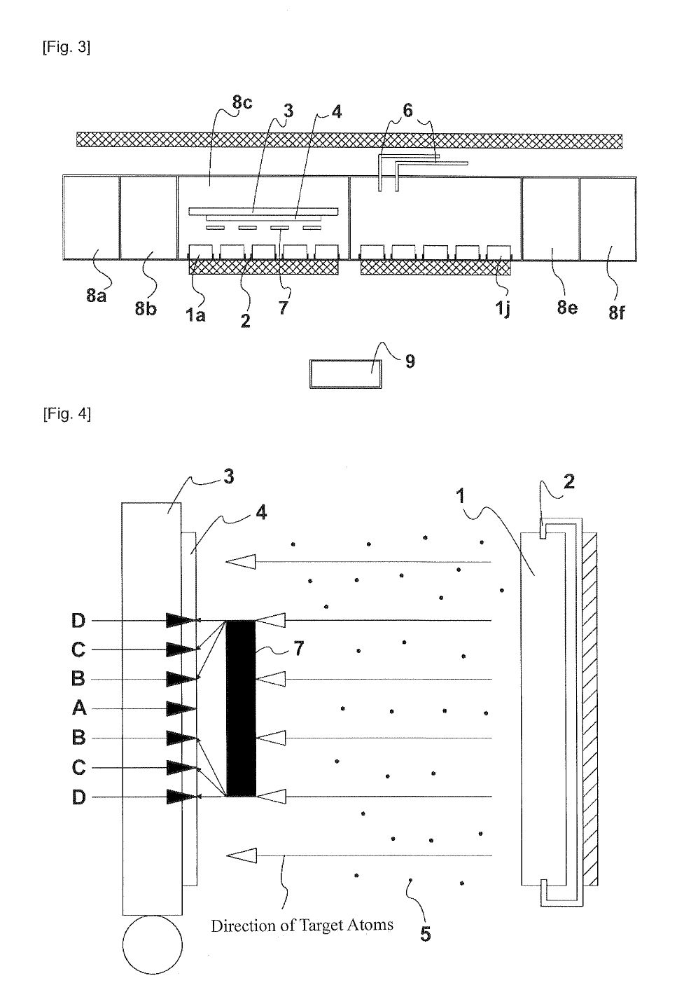

FIG. 3 is a configuration view of a vacuum deposition method for forming gradient patterns using a vacuum device according to the present invention. As shown in FIG. 3, the vacuum device according to the present invention has blocking members 7 interposed between the substrate 4 and the metal targets 1, which is additionally mounted on the configuration of the conventional vacuum deposition device.

FIG. 4 is a schematic diagram showing the principle for forming the gradient patterns through vacuum deposition using the vacuum device according to the present invention and is a plan view like FIG. 3.

In case that the blocking members 7 are interposed between the metal targets 1 and the substrate 4, some of the target atoms 5 are blocked from being deposited on the surface of the substrate 4 by the blocking members 7, but some of the target atoms 5, which are unaffected by the blocking members 7, are deposited on the surface of the substrate 4.

However, when the neutral target atoms 5, which pop out from the metal targets 1, are deposited on the surface of the substrate 4, most of target atoms 5 go straight toward the substrate 4, but because the target atoms 5 go straight toward the substrate 4 in the concept of spread while going straight, the target atoms 5 are deposited also onto the substrate 4, which is located at the back of the blocking members 7.

Like the phenomenon that when sunlight shines on an object and casts the object's shadow on a face of something, which is located behind the object, a central part of the shadow is cast darker but an edge part of the shadow is cast lighter than the central part if there is a predetermined interval between the object and the face of something. As shown in FIG. 4, because the target atoms 5 get little influence by the blocking members 7 at an area D of the substrate 4, which corresponds to an edge part of the blocking member 7, but is blocked by the blocking member 7 at an area A of the substrate 4, which corresponds to the center of the blocking member 7, the target atoms 5 are noticeably low in deposition rate.

That is, in the areas A, B, C and D, the deposition rate of the target atoms 5, which are deposited on the surface of the substrate 4, is gradually declined from the area D to the area A, and such a declination in deposition rate is indicated as a gradient pattern.

In consideration of the basic principle of coating that protects the substrate 4 by forming a film on the surface of the substrate 4, the blocking members 7 are made of a material, which is 100 percent effective to block penetration of atoms 5, and according to circumstances, they may be made of a material, which can partially penetrate the atoms 5.

As the material, which can partially penetrate the atoms 5, porous fabric may be used.

The gradient patterns may be produced in various ways according to intervals, directions and angles of the blocking members 7. Additionally, the gradient patterns may be produced differently according to shapes and widths of the blocking members 7 and according to how far the blocking members 7 are from the substrate 4.

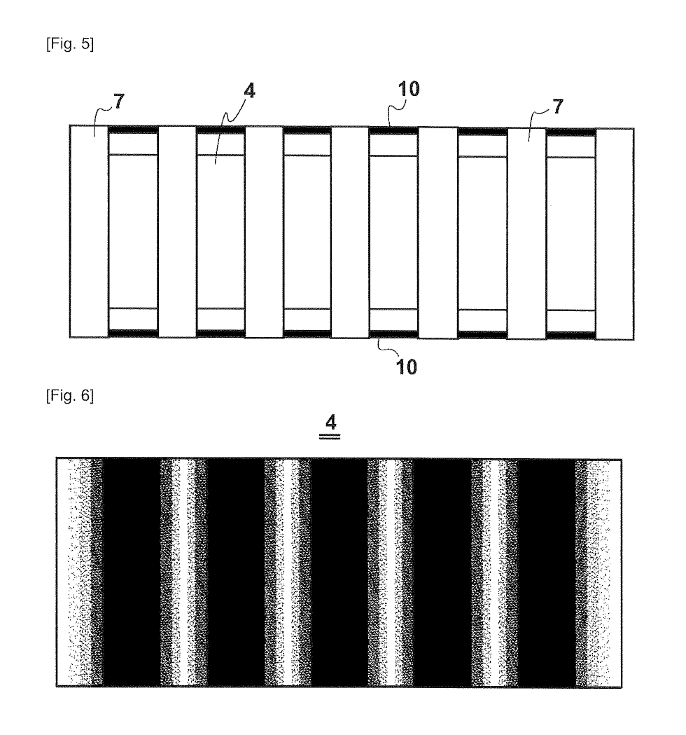

Particularly, as shown in FIG. 5, if the blocking members 7 are mounted in a movable manner by a guide rail 10, a user can easily control the intervals of the blocking members as he or she wants.

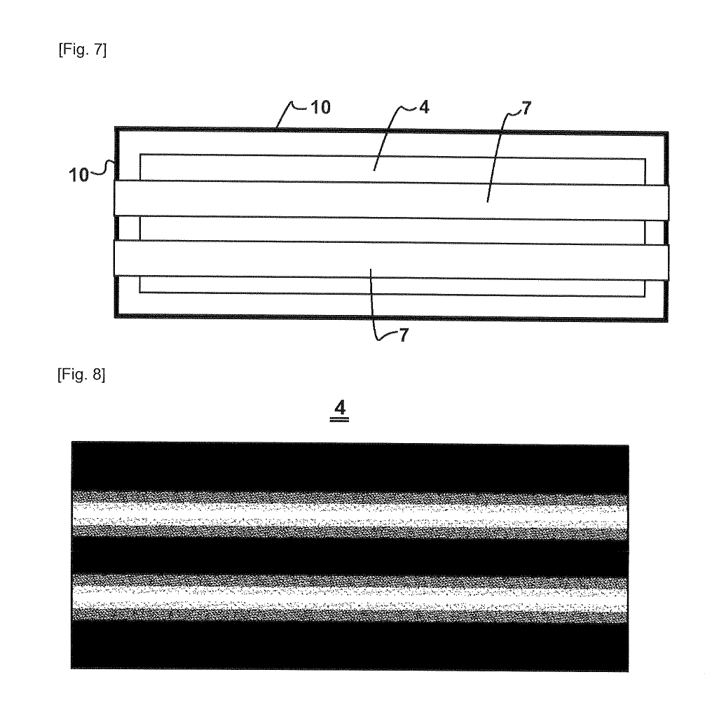

Moreover, as shown in FIG. 7, the guide rail 10 is formed in a rectangle, the blocking members 7 can be arranged vertically or horizontally without regard to their shape. Assumed that the rectangular guide rail 10 is on a plane with X and Y axes, the interval between the blocking members 7 and the substrate 4 can be controlled by a guide rail of Z axis (not shown in the drawing) additionally mounted, whereby the gradient patterns can be controlled.

The vacuum deposition for forming the gradient patterns can be widely applied to refrigerators, TVs, washing machines, air conditioners, mobile phones, notebooks, microwaves, gas ovens, building materials, and so on because it is environmental-friendly and is insensitive to temperature change.

### Embodiment 1

Titanium was used as the metal targets 1, and the degree of vacuum inside the chambers 8 was 8.5K×10⁻⁴ TORR and argon gas of 450 SCCM was injected by two DC sputters of 5 kw. After that, as shown in FIG. 5, the plural (seven) blocking members 7 were vertically arranged at a predetermined interval between the substrate 4 and the metal targets 1, and then, plasma was irradiated, and thereby, vertically gradient patterns were produced as shown in FIG. 6.

In FIG. 6, black parts are parts which were not affected by the blocking members 7, but white parts are parts which had a relatively great influence by the blocking members.

### Embodiment 2

Titanium was used as the metal targets 1, and the degree of vacuum inside the chambers 8 was 8.5K×10⁻⁴ TORR and argon gas of 450 SCCM was injected by two DC sputters of 5 kw. After that, as shown in FIG. 7, the plural (two) blocking members 7 were horizontally arranged at a predetermined interval between the substrate 4 and the metal targets 1, and then, plasma was irradiated, and thereby, the deposited form was indicated as shown in FIG. 6.

In FIG. 8, black parts are parts which were not affected by the blocking members 7, but white parts are parts which had a relatively great influence by the blocking members.

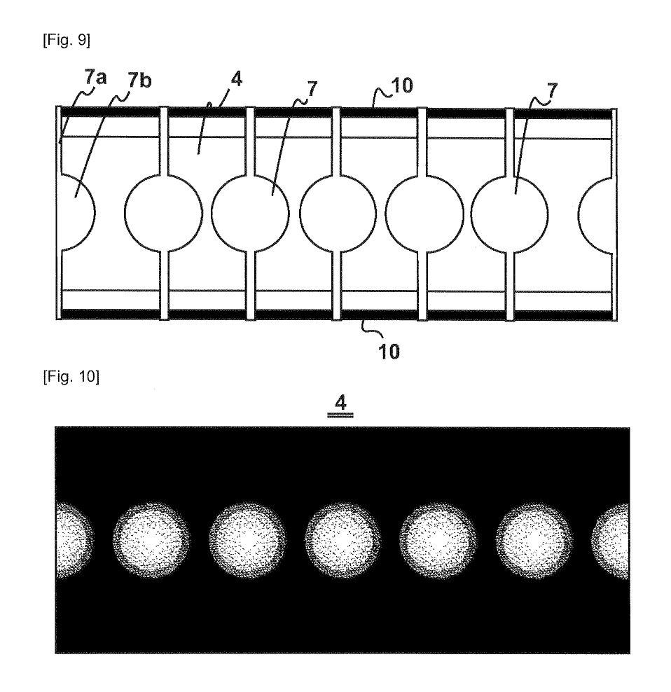

FIG. 9 is a view showing another example of the blocking members according to the present invention, and FIG. 10 is a view showing a gradient pattern formed by the blocking members of FIG. 9.

If blocking members 7, each of which includes a circular body 7b and projections 7a formed on right and left sides or upper and lower sides of the circular body 7b and joined to the guide rail 10 as shown in FIG. 9, are used, gradient patterns shown in FIG. 10 can be produced.

In this instance, the projections 7a must have minimum thickness or minimum area in order not to be affected by the blocking effect when the target atoms 5 are deposited on the substrate 4.

Furthermore, a printing step (solid printing and baked printing) or an etching step may be added before or after the deposition process for forming the gradient patterns, or a film or a PET with characters, patterns, photographs or images may be adhered on the front surface or the rear surface of the deposited face, whereby it may provide an enhanced artistic value of the products in addition to the gradient effect.

Particularly, in the baked printing, when a drying temperature is rapidly applied to a printed face by a drier after printing, there are unique cracks because cohesiveness of ink becomes weak, and in this instance, the rear face is deposited to form a film. Then, a deposited coating is formed between the cracks to thereby show unique shape and color according to the formed film, whereby it may provide an enhanced esthetic sense.

While the present invention has been described with reference to the particular illustrative embodiment, it is not to be restricted by the embodiment but only by the appended claims. It is to be appreciated that those skilled in the art can change or modify the embodiment without departing from the scope and spirit of the present invention.

1. A vacuum deposition method for forming gradient patterns using a vacuum device, wherein the vacuum device comprises vacuum chambers (8) containing a substrate (4) and metal targets (1) therein and a blocking member (7) interposed between the substrate (4) and the metal targets (1), and wherein the vacuum deposition method comprises the steps of applying voltage to the metal targets (1); and depositing atoms (5) popping out from the metal targets (1) onto the substrate (4) in such a way that the amount of atoms deposited on the substrate (4) is gradually decreased from the edge toward the center of the blocking member (7) due to interruption of the blocking member (7).

2. The vacuum deposition method according to claim 1, wherein at least one blocking member (7) is interposed between the substrate (4) and the metal targets (1) so as to depositely form various types of gradient patterns on the substrate (4).

3. The vacuum deposition method according to claim 1, wherein the blocking member (7) is made of a material, which allows transmission of only a predetermined amount of metal atoms (5) to penetrate.

4. The vacuum deposition method according to claim 1, wherein the blocking member (7) is constructed of combination of materials having different transmission rates on the metal atoms (5) in order to form a gradient pattern.

5. The vacuum deposition method according to claim 1, wherein a printing step or an etching step is added before or after the gradient-patterned deposition process, or a film or a PET is adhered on the front surface or the rear surface of the deposited face in order not only to provide not only the gradient effect but also to form characters, patterns, photographs or images on the deposited surface.

6. The vacuum deposition method according to claim 1, wherein the metal targets (1) are selectively made of one of non-conductive materials, such as silicon (Si) and tin (Sn), and conductive materials, such as titanium (Ti), chrome (Cr), aluminum (Al), nickel (Ni), stainless steel (STS), gold, and silver (Ag).

7. The vacuum deposition method according to claim 1, wherein the substrate (4) is selectively made of one of nonmetallic materials, such as glass, acrylic, polycarbonate, and PET films, and metallic materials.

8. The vacuum deposition method according to claim 1, wherein the blocking member (7) is controllable in its position by a guide rail (10).
